(19) United States
(12) Patent Application Publication
(10) Pub. No.: US 2026/0006869 A1
(43) Pub. Date: Jan. 1, 2026

(54) BACKSIDE SUBSTRATE DIELECTRIC BREAK

(71) Applicant: INTERNATIONAL BUSINESS MACHINES CORPORATION, ARMONK, NY (US)

(72) Inventors: Masoud Zabihi, Schenectady, NY (US); Ruilong Xie, Niskayuna, NY (US); Robert Gauthier, Williston, VT (US); Anindya Nath, Watervliet, NY (US); Anthony I-Chih Chou, Guilderland, NY (US)

(21) Appl. No.: 18/755,626

(22) Filed: Jun. 26, 2024

(51) Int. Cl. H01L 29/06; H01L 21/8238; H01L 23/522; H01L 23/528; H01L 27/092; H01L 29/423; H01L 29/66; H01L 29/775; H01L 29/786

(52) U.S. Cl. CPC H10D 62/115; H01L 23/5226; H01L 23/5283; H10D 30/014; H10D 30/43; H10D 30/6735; H10D 30/6757; H10D 62/121; H10D 84/017; H10D 84/0186; H10D 84/0188; H10D 84/038; H10D 84/85

(57) ABSTRACT

A semiconductor device includes a passive device including a set of P-type doped regions, a set of N-type doped regions, a first N-well region and a second N-well region below the set of P-type doped regions and the set of N-type doped region, respectively, a first shallow trench isolation (STI) between the first N-well region and the second N-well region, a substrate below the first STI; and a dielectric break within the substrate. The dielectric break is vertically extended from the first STI to a bottom interlayer dielectric (BILD) below the substrate.

### BACKGROUND

### Technical Field

The present disclosure generally relates to semiconductors, and more particularly, to semiconductors with backside substrate break patterning and dielectric fill structure, and methods of creation thereof.

### Description of Related Art

The relentless miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip.

### SUMMARY

According to an embodiment, a semiconductor device includes a passive device including a set of P-type doped regions, a set of N-type doped regions, a first N-well region and a second N-well region below the set of P-type doped regions and the set of N-type doped region, a first shallow trench isolation (STI) between the first N-well region and the second N-well region, a substrate below the first STI, and a dielectric break within the substrate. The dielectric break is vertically extended from the first STI to a bottom interlayer dielectric (BILD) below the substrate.

In one embodiment, the dielectric break and the first STI isolate the first N-well region and the second N-well region.

In one embodiment, the dielectric break is made of silicon.

In one embodiment, the passive device is electrically connected to a back end of line (BEOL) through a first via.

In one embodiment, the semiconductor device includes an active device including source/drain regions, gate regions, and a backside contact.

In one embodiment, the active device is a field-effect transistor (FET).

In one embodiment, the active device further comprises alternative layers extended horizontally between two adjacent source/drain regions.

In one embodiment, the active device is electrically connected to a back end of line (BEOL) through a second via.

In one embodiment, the alternative layer includes silicon.

According to an embodiment, a method for fabrication of a semiconductor device, the method including forming a passive device including forming a set of P-type doped regions, forming a set of N-type doped regions, forming a first N-well region and a second N-well region below the set of P-type doped regions and the set of N-type doped regions, forming a first shallow trench isolation (STI) between the first N-well region and the second N-well region, forming a substrate below the first STI, and forming a dielectric break within the substrate. The dielectric break is vertically extended from the first STI to a bottom interlayer dielectric (BILD) below the substrate.

In one embodiment, the method includes isolating the first N-well region and the second N-well region by the dielectric break and the first STI.

In one embodiment, the dielectric break is made of silicon.

In one embodiment, the method includes establishing an electrical connection between the passive device and a back end of line (BEOL) through a first via.

In one embodiment, the method includes forming an active device including forming source/drain regions, forming gate regions between the source/drain regions, and forming a backside contact below one of the source/drain regions.

In one embodiment, the active device is a field-effect transistor (FET).

In one embodiment, the method includes forming alternative layers extended horizontally between two adjacent source/drain regions.

In one embodiment, the method includes establishing an electrical connection between the active device and a back end of line (BEOL) through a second via.

In one embodiment, the alternative layer includes silicon.

According to an embodiment, a semiconductor device includes a passive device including a shallow trench isolation (STI), a substrate below the STI, and a dielectric break within the substrate. The dielectric break and the STI isolate a first N-well region and a second N-well region in the passive device. The semiconductor device includes an active device.

In one embodiment, the passive device further includes a set of-type doped regions, a set of N-type doped regions. The first N-well region and the second N-well region are located below the set of P-type doped regions and the set of N-type doped region.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates a sideview of a conventional semiconductor device.

FIG. 2 illustrates a semiconductor device, in accordance with some embodiments.

FIGS. 3A-3B illustrate a semiconductor device after the formation of the front end of line, middle end of line, and back end of line, in accordance with some embodiments.

FIGS. 4A-4B illustrate a semiconductor device after wafer flip and substrate removal, in accordance with some embodiments.

FIGS. 5A-5B illustrate a semiconductor device after patterning of the dielectric break, in accordance with some embodiments.

FIGS. 6A-6B illustrate a semiconductor device after the removal of the exposed etch stop layer, in accordance with some embodiments.

FIGS. 7A-7B illustrate a semiconductor device after the removal of the remaining substrate, in accordance with some embodiments.

FIGS. 8A-8B illustrate a semiconductor device after the formation of the backside interlayer dielectric, in accordance with some embodiments.

FIGS. 9A-9B illustrate a semiconductor device after the patterning of the backside contact, in accordance with some embodiments.

FIGS. 10A-10B illustrate a semiconductor device after the backside contact metallization, in accordance with some embodiments.

FIGS. 11A-11B illustrate a semiconductor device after the after the formation of the backside metal layer, in accordance with some embodiments.

FIG. 12 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

Backside interconnect is recognized as the industry go-to direction for advancing semiconductor technology. By routing interconnections on the backside of the semiconductor wafer, this approach effectively increases the available area for active device components on the frontside, thereby enhancing overall device performance and density. The implementation of backside interconnects allows for more efficient power distribution and signal routing, reducing resistance and inductance associated with longer interconnect paths. Preventing latch-up in integrated circuits is desired due to its potential to cause catastrophic failure. Latch-up refers to the inadvertent creation of a low-impedance path between the power supply rails, typically triggered by certain electrical conditions such as overshoot, undershoot, or transient currents. This low-impedance path can lead to excessive current flow, causing overheating, circuit malfunction, or permanent damage to the integrated circuit. Effective latch-up prevention strategies require careful layout design, proper isolation techniques, and the incorporation of guard rings or substrate ties to mitigate the risk of latch-up occurrences.

In semiconductor devices, overshoot and undershoot are phenomena that can adversely affect signal integrity. Overshot occurs when the voltage of a signal exceeds its intended maximum value during a transition, often due to the inductive and capacitive properties of the interconnects. This excessive voltage can lead to signal distortion, potential damage to the device, and increased electromagnetic interference (EMI). Similarly, undershoot refers to the scenario where the signal voltage drops below its intended minimum value, which can also cause signal integrity issues, increased susceptibility to noise, and potential triggering of unintended states in digital circuits. Both overshoot and undershoot need to be considered in high-speed and high-frequency circuit design, necessitating the use of proper termination techniques, controlled impedance routing, and careful signal integrity analysis to minimize their impact.

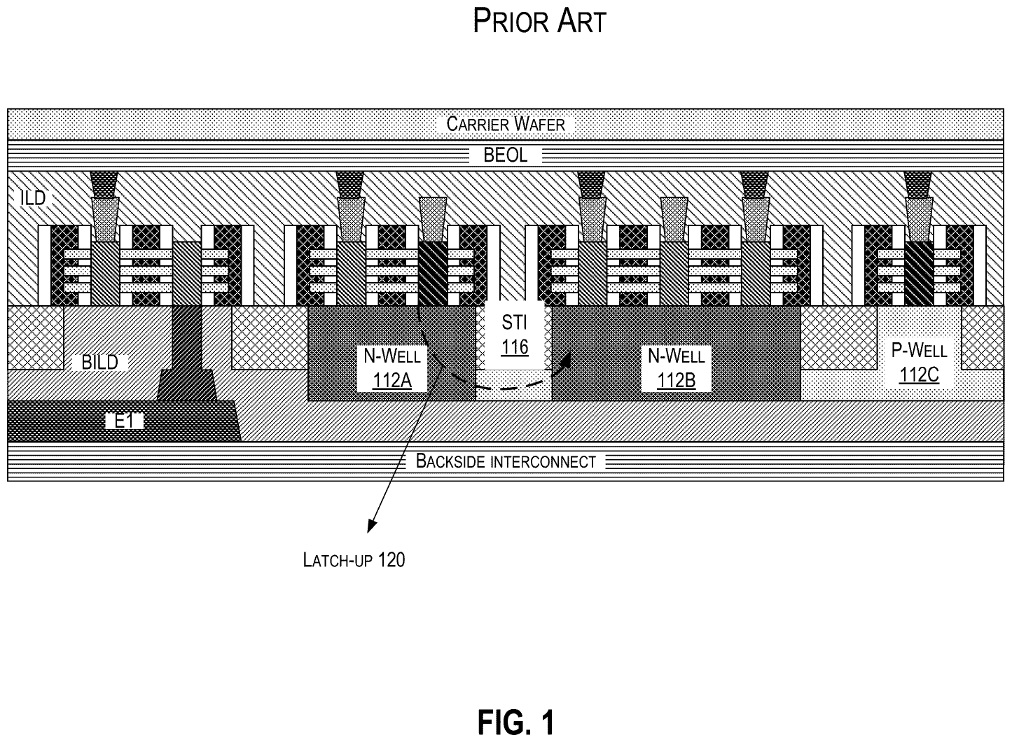

The parasitic PNPN silicon-controlled rectifier (SCR) structure in complementary metal-oxide-semiconductor (CMOS) technology is a factor in latch-up phenomena. The parasitic SCR is formed inadvertently during the fabrication of CMOS devices, consisting of a PNP transistor and an NPN transistor that are interconnected in such a way that they can form a positive feedback loop. When certain conditions, such as high current injection or excessive voltage, are met, this feedback loop can become self-sustaining, leading to a latch-up condition. Once triggered, the parasitic SCR can conduct a significant amount of current, resulting in elevated temperatures, potential destruction of the device, and failure of the integrated circuit. FIG. 1 illustrates the formation of the parasitic PNPN SCR which causes the latch-up 120. The latch-up 120 can occur between a first N-well region 112A below the P-type doped regions and the N-type doped regions and a second N-well region 112B and via the STI 116 and a P-well region 112C.

In view of the above considerations, disclosed is a semiconductor device with a substrate break on the backside of the semiconductor device to prevent the latch-up in the backside of the semiconductor device. To that end, a backside silicon break and backside fill is provided on the backside of the semiconductor device to isolate the N-well and the P-well, thus minimizing the risk of latch-up.

Accordingly, the teachings herein provide methods and systems of semiconductor device formation with backside substrate break patterning and dielectric fill. The techniques described herein may be implemented in a number of ways. Example implementations are provided below with reference to the following figures.

Example Semiconductor Device with Backside Substrate Break Structure

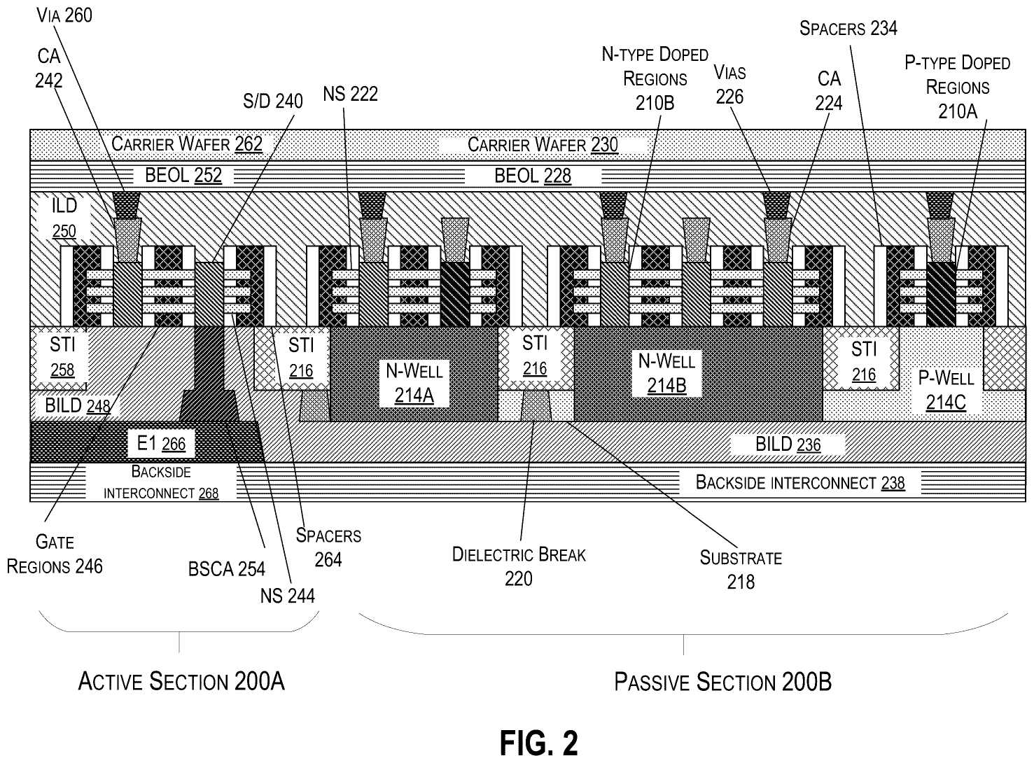

Reference now is made to FIG. 2, which is a simplified cross-section view of a semiconductor device, consistent with an illustrative embodiment. In various embodiments, the semiconductor device includes an active section 200A and a passive section 200B.

The passive section 200B includes a set of P-type doped regions 210A, a set of N-type doped regions 210B, a first N-well region 214A, a second N-well region 214B, a P-well region 214C, a first shallow trench isolation, STI 216 between the first N-well region 214A and the second N-well region 214B, a substrate 218 below the STI 216, a dielectric break 220 within the substrate 218, a set of nanosheet gates, NS 222, frontside contacts, CA 224, a set of vias 226, a back end of line, BEOL 228, a carrier wafer 230, an interlayer dielectric, ILD 232, spacers 234, a bottom ILD, BILD 236, and a backside interconnect 238.

Each pair of the set of N-type doped regions 210B and the set of P-type doped regions 210A can be created by doping two regions, one with a type P dopant, which introduces an excess of positive charge carriers (holes), and the other with a type N dopant, which introduces an excess of negative charge carriers (electrons). Similarly, the first N-well region 214A, the second N-well region, and the P-well region 214C can be doped with N-type and P-type dopants, respectively.

An N-well region and a P-well region can form the p-n junction of the passive section 200B. The p-n junction can control the flow of electrical current within the semiconductor device. The p-n junction can be created by doping two adjacent regions, one with a type P dopant, which introduces an excess of positive charge carriers (holes), and the other with a type N dopant, which introduces an excess of negative charge carriers (electrons). At the interface between the P and N regions, a depletion region forms due to the diffusion of electrons from the N region into the P region and the diffusion of holes in the opposite direction. Such a diffusion process continues until the electric field created by the accumulation of charge at the junction balances the diffusion forces, resulting in a zone depleted of free charge carriers. In its natural state, the p-n junction allows current to flow more easily in one direction than in the opposite. When forward biased, i.e., positive voltage applied to the P side relative to the N side, the depletion region narrows, lowering the barrier for charge carriers to move across the junction, and allowing current to flow through the device. Conversely, when reverse-biased, i.e., negative voltage applied to the P side, the depletion region widens, increasing the barrier for charge movement, and significantly reducing the flow of current.

The STI 216 can electrically isolate different components by filling the trenches with an insulating material, such as silicon dioxide. The STI 216 can prevent electrical interference and crosstalk between adjacent devices, ensuring that each component operates independently without affecting its neighbors.

The substrate 218 can be a silicon substrate. In some embodiments, the substrate 218 is doped with a P-type dopant. In some embodiments, the substrate 218 can provide the mechanical support necessary for the integrated circuit's construction.

As mentioned earlier, latch-up can arise within peripheral or internal circuits, either within a single circuit (intra-circuit) or between multiple circuits (inter-circuit). For example, latch-up can occur when a PNPN structure transitions from a low-current high-voltage state to a high-current low-voltage state through a negative resistance region, resulting in an S-Type I-V (current/voltage) characteristic. Latch-up can be particularly initiated by an equivalent circuit consisting of cross-coupled PNP and NPN transistors. With the base and collector regions cross-coupled, current from one device initiates the second device through “regenerative feedback.” These PNP and NPN elements can be diffusions or implanted regions of other circuit elements (such as PFETs, NFETs, and resistors) or actual PNP and NPN bipolar transistors. The PNPN configuration can be formed with a p-diffusion in an n-well and an n-diffusion in a p-substrate, creating a “parasitic PNPN” structure. In such instances, the well and substrate regions are inherently involved in the latch-up current exchange within the device.

Further, latch-up can be triggered by interactions between electrostatic discharge (ESD) devices, input/output (I/O) off-chip drivers, and adjacent circuitry, particularly through substrate initiation from overshoot and undershoot phenomena. Such factors can be generated by CMOS off-chip driver circuitry, receiver networks, and ESD devices. In CMOS I/O circuitry, undershoot and overshoot can lead to substrate injection, where simultaneous switching may result in both noise injection and latch-up conditions. Supporting elements such as pass transistors, resistor elements, test functions, over-voltage dielectric limiting circuitry, bleed resistors, keeper networks, and other components can further contribute to substrate noise injection and latch-up.

As the semiconductor device technology scales down, the reduced p+/n+ spacing lowers the trigger threshold, increasing the susceptibility to CMOS latch-up. The scaling of STI aspect ratios can also heighten CMOS technology's vulnerability to latch-up. Additionally, vertical scaling of wells and lower implant doses for n-wells and p-wells have increased lateral parasitic bipolar current gains, reducing latch-up robustness. The transition from p+ substrates to low-doped p− substrates can diminish latch-up robustness. Although n-wells used as guard ring structures can mitigate latch-up issues, mixed-signal applications and radio frequency chips have increased concerns for noise reduction, leading to further reductions in substrate doping concentration and, consequently, lower latch-up immunity in these technologies. Latch-up can also be triggered by voltage or current pulses on power supply lines. Transient pulses on power rails (such as the substrate or wells) can initiate latch-up processes. Additionally, latch-up can result from stimuli to the well or substrate external to the thyristor structure region by minority carriers.

The dielectric break 220 can prevent the formation of PNPN SCR and hence, latch-up, as the dielectric break 220 can isolate the N-wells and break the possible circuit between the N-wells. Unlike the traditional semiconductors, which only include STI as an isolation layer between the N-wells, the semiconductor device shown in FIG. 2 includes the dielectric break 220 below the STI 216 to completely isolate the N-wells. The inclusion of the BILD 236 below the STI 216 and the dielectric break 220 ensures that the N-wells are not electrically connected to each other on the backside of the semiconductor device. In some embodiments, the dielectric break 220 and the STI 216 can isolate the first N-well region 214A and the second N-well region 214B. The dielectric break 220 can be made of silicon.

The NS 222 can be alternating, vertically oriented sheets, which can drive current in a small footprint area. In some embodiments, the NS 222 includes silicon nanowires. In other words, the NS 222 includes three-dimensional structures in the gate, which are extended from a source region towards a drain region.

The CA 224, located over the set of P-type doped regions 210A and the set of N-type doped regions 210B, can establish connections between the set of P-type doped regions 210A and the set of N-type doped regions 210B and the BEOL 228 through the set of vias 226. The CA 224 can ensure efficient electrical routing and connectivity within the passive section 200B. The fabrication of the CA 224 can involve lithography and etching processes to define the contact area. The CA 224 can be made using conductive materials such as copper (Cu) or tungsten (W).

The BEOL 228 can include metal interconnects and other structures on the upper layers of a passive section 200B to form a network of connections that link various components of the passive section 200B.

The ILD 232 can be a layer of insulating material to electrically isolate and provide mechanical support between different layers of conducting and active components. The ILD 232 can enable efficient signal transmission, reduce crosstalk, and ensure the proper functioning of the passive section 200B. In an embodiment, the ILD 232 can electrically isolate adjacent conducting layers or active components in the passive section 200B. By providing insulation between different layers, the ILD 232 can prevent electrical shorts, reduce (e.g., minimize) leakage current, and ensure that signals are directed only along the desired pathways. In some embodiments, the ILD 232 can help reduce parasitic capacitance between adjacent metal interconnects or active devices and provide mechanical support to the passive device's structure.

In several embodiments, the BILD 236 can provide structural support to the passive section 200B by maintaining the mechanical integrity and stability of the passive section 200B. The BILD 236 can further help prevent the warping, bending, or cracking of the substrate, particularly during the manufacturing process or subsequent handling. The BILD 236 can ensure that the passive section 200B remains mechanically robust and maintains its dimensional stability.

In an embodiment, the BILD 236 can also serve as a planarization layer in the passive section 200B fabrication process. As various layers are deposited and patterned on the front side of the passive section 200B, irregularities or topographic variations may arise. The BILD 236 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 236 can contribute to improved overall passive device performance. In several embodiments, BILD 236 can facilitate wafer-level testing of the passive section 200B. By providing electrical isolation between the active regions and the backside contact, individual passive device or elements on the passive section 200B can be electrically accessed and tested without interference from neighboring devices or components. This enables efficient and accurate wafer-level testing, ensuring quality control during semiconductor manufacturing.

The backside interconnect 238 can provide backside electrical connection between the passive section 200B and other devices.

The active section 200A, which can be field-effect transistor (FET), includes source/drain regions, S/D 240, frontside contacts, CA 242, a second set of nanosheet gates, NS 244, gate regions 246, BILD 248, ILD 250, BEOL 252, a backside contact, BSCA 254, a STI 258, a via 260, a carrier wafer 262, spacers 264, a metal line, E1 266, and a backside interconnect 268.

Generally, the source/drain regions, such as the S/D 240, are salient components that play relevant roles in the semiconductor device's operation. In various embodiments, the S/D 240 is region within the semiconductor material, e.g., the semiconductor device, where the current flows in and out of the semiconductor device. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

The CA 242, located over the S/D 240, can establish connections between the S/D 240 and the BEOL 252. The CA 242 can ensure efficient electrical routing and connectivity within the active section 200A. The fabrication of the CA 242 can involve lithography and etching processes to define the contact area. The CA 242 can be made using conductive materials such as copper (Cu) or tungsten (W).

The NS 244 can be alternating, vertically oriented sheets, which can drive current in a small footprint area. In some embodiments, NS 244 includes silicon nanowires. In other words, NS 168 includes three-dimensional structures in the gate, which are extended from a source region towards a drain region.

In various embodiments, the gate regions 246 serve as control elements that regulate the flow of current through the active section 200A. The gate regions 246 can be composed of a conductive material. The gate regions 246 can control the flow of electric current between the source and drain regions. In addition to acting as a switch, modulating the gate voltage can enable the gate regions 246 to control the current flowing through the channel region, resulting in amplified output signals.

In an embodiment, the gate regions 246 can enable the implementation of Boolean active operations, such as AND, OR, and NOT, by controlling the flow of current based on the input voltages. In some embodiments, the gate regions 246, along with other active device components, can facilitate the miniaturization and integration of electronic circuits. The ability to control the channel region's conductivity through the gate voltage allows for compact and highly efficient circuit designs.

In several embodiments, the BILD 248 can provide structural support to the semiconductor device by maintaining the mechanical integrity and stability of the active section 200A. The BILD 248 can further help prevent the warping, bending, or cracking of the substrate, particularly during the manufacturing process or subsequent handling. The BILD 248 can ensure that the active section 200A remains mechanically robust and maintains its dimensional stability.

In an embodiment, the BILD 248 can also serve as a planarization layer in the active section 200A fabrication process. As various layers are deposited and patterned on the front side of the active section 200A, irregularities or topographic variations may arise. The BILD 248 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 248 can contribute to improved overall semiconductor device performance. In several embodiments, BILD 248 can facilitate wafer-level testing of the semiconductor device. By providing electrical isolation between the active regions and the backside contact, individual active device or elements on the active section 200A can be electrically accessed and tested without interference from neighboring devices or components. This enables efficient and accurate wafer-level testing, ensuring quality control during semiconductor manufacturing.

The ILD 250 can be a layer of insulating material to electrically isolate and provide mechanical support between different layers of conducting and active components. The ILD 250 can enable efficient signal transmission, reduce crosstalk, and ensure the proper functioning of the active section 200A. In an embodiment, the ILD 250 can electrically isolate adjacent conducting layers or active components in the active section 200A. By providing insulation between different layers, the ILD 250 can prevent electrical shorts, reduce (e.g., minimize) leakage current, and ensure that signals are directed only along the desired pathways. In some embodiments, the ILD 250 can help reduce parasitic capacitance between adjacent metal interconnects or active devices and provide mechanical support to the active device's structure.

The BEOL 252 can include metal interconnects and other structures on the upper layers of the active section 200A to form a network of connections that link various components of the active section 200A.

The BSCA 254 is a region on the backside of the active section 200A where electrical connections are made. By establishing the electrical contacts, the BSCA 254 can ensure the proper functioning of the active section 200A and facilitates electrical signal transmission. The BSCA 254 can serve as a thermal interface between the active section 200A and a heat sink or other cooling mechanisms. By establishing direct contact with the substrate, the BSCA 254 can conduct the heat away from the active device 002A, and contribute to improved thermal dissipation. In some embodiments, the BSCA 254 can help mitigate parasitic effects, such as substrate coupling or substrate noise, from the active section 200A. In further embodiments, the BSCA 254 can allow for increased integration density in the active section 200A.

The STI 258 helps prevent electrical crosstalk and interference between adjacent components, allowing for the proper functioning of integrated circuits. The STI 258 can be an insulating material or layer used to isolate and provide electrical insulation between the passive device's various regions and components, and to prevent unwanted electrical contact between such regions and components, ensuring the proper functioning and integrity of the passive device 100B. In various embodiments, the STI 258 can act as a protective layer, shielding the active regions of the passive device from external contaminants, moisture, and mechanical stress. The STI 258 can further help prevent physical damage, such as scratches or particle contamination, which could adversely affect passive device performance. Additionally, the STI 258 can act as a barrier against moisture ingress, which can cause corrosion and degradation of the passive device's components.

The STI 258 can be extended vertically and partially isolate the first N-well region 214A and the second N-well regions 214B.

It should be noted that, since the active section 200A and the passive section 200B can be adjacent to each other on the semiconductor device, the active section 200A and the passive section 200B can share a common carrier wafer, STI, and backside interconnect. In other words, in some embodiments, the carrier wafer 230 can be the same as the carrier wafer 262. Similarly, in some embodiments, the backside interconnect 238 can be the same as the backside interconnect 268. Similarly, in some embodiments, the STI 216 can be the same as the STI 258.

Example Act of Fabrication of Semiconductor Device with Backside Substrate Break

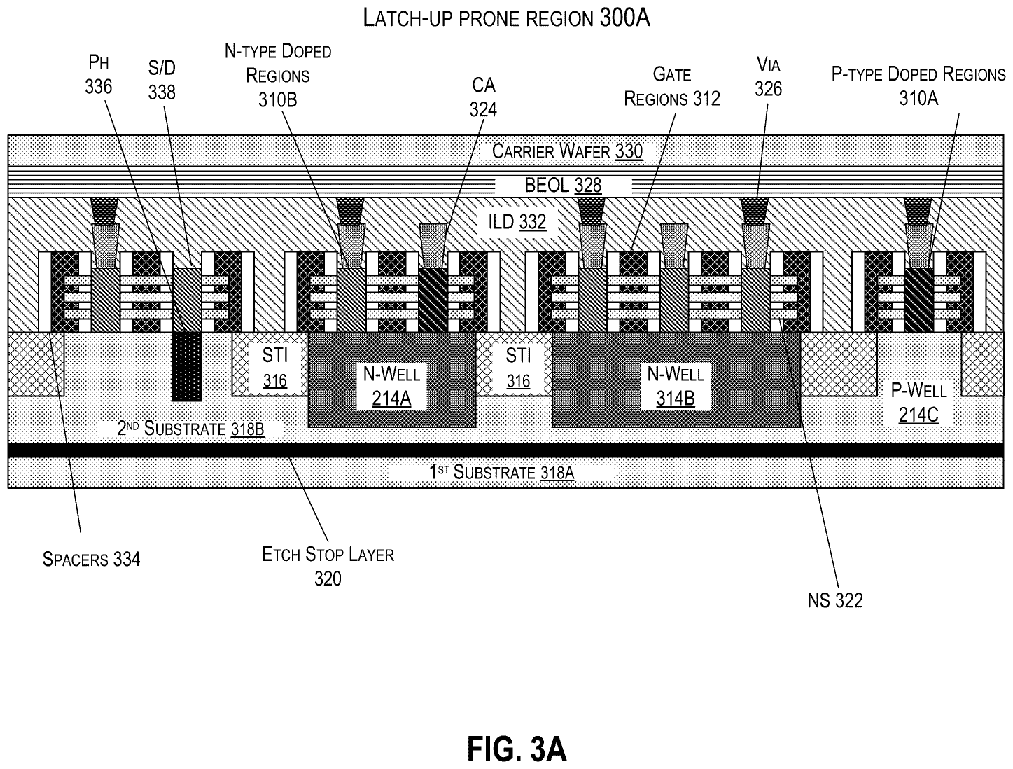

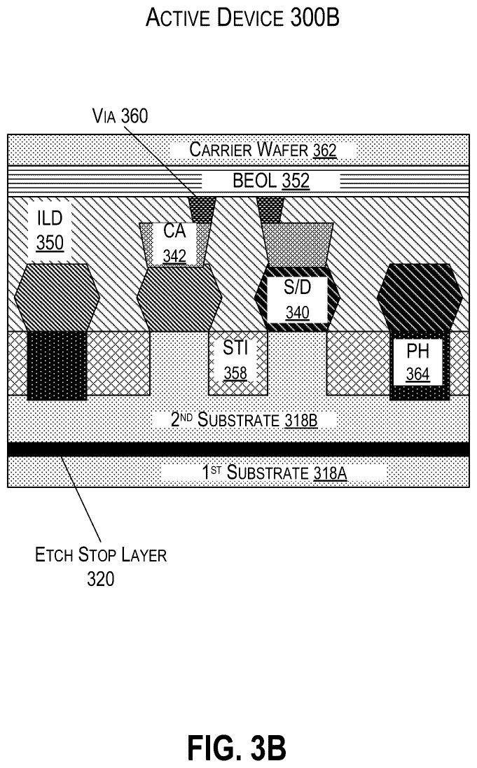

With the foregoing description of an example semiconductor device, it may be helpful to discuss an example process of manufacturing the same. To that end, FIGS. 3-11 illustrate various acts in the manufacture of a semiconductor device, consistent with illustrative embodiments. Figures denoted by A show the acts of fabrication of the semiconductor device in the latch-up prone region between the active device and the passive device, and figures denoted by B illustrate the acts of fabrication of the active device.

Reference now is made to FIGS. 3A-3B, which are simplified cross-section views of a semiconductor device, after the front end of line (FEOL), middle of line (MOL), and BEOL, consistent with an illustrative embodiment. As noted above, the semiconductor device includes a latch-up prone region 300A (between the passive device and the active device) and an active device 300B.

The latch-up prone region 300A can a set of P-type doped regions 310A, a set of N-type doped regions 310B, gate regions 312, a first N-well region 314A, a second N-well region 314B, a P-well region 314C, a first shallow trench isolation, STI 316 between the first N-well region 314A and the second N-well region 314B, a first substrate 318A, a second substrate 318B, an etch stop layer 320, a set of nanosheet gates, NS 322, frontside contacts, CA 324, a first set of vias 326, a back end of line, BEOL 328, a carrier wafer 330, an interlayer dielectric, ILD 332, and spacers 334. The transistor section of the latch-up prone region 300A can include set of source/drain regions, S/D 338, and a placeholder, PH 336, below one of the S/D.

The active device 300B, which can be a FET, includes source/drain regions, S/D 340, frontside contacts, CA 342, ILD 350, BEOL 352, a STI 358, a second set of vias 360, a carrier wafer 362, PH 364, the first substrate 318A, the second substrate 318B and the etch stop layer 320. It should be noted that, in various embodiments, the latch-up prone region 300A and the active device 300B can share one or more of the BEOL, carrier wafer, first substrate, second substrate, etch stop layer, ILD and STI can be common.

In the illustrative example depicted in FIGS. 3A-3B, the semiconductor device is depicted as being on silicon as the first substrate 318A and the second substrate 318B, while it will be understood that other types as the first substrate 318A and the second substrate 318B may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 318A and the second substrate 318B can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 320 is formed over the first substrate 318A. The etch stop layer 320 can be a thin layer of material incorporated into the structure of the semiconductor device to provide a selective barrier against etching processes, preventing further removal of underlying materials during fabrication. The etch stop layer 320 can enable precise control over the etching depth and help define the desired device dimensions. The etch stop layer 320 can further provide a stopping point for the etching process, ensuring that specific layers or regions are not etched beyond a certain point, leading to accurate patterning and control of critical features. The etch stop layer 320 can create a distinct separation between different layers or components within the device structure, and prevent the undesired etching of underlying layers or materials, enabling the creation of complex, multi-layered structures with well-defined interfaces and boundaries. In some embodiments, the etch stop layer 320 acts as a protective barrier for sensitive or delicate materials to shield such materials from aggressive etchants, preventing damage or degradation during subsequent fabrication steps.

In some embodiments, prior to forming the etch stop layer 320, the first substrate 318A is prepared by cleaning and removing any impurities or oxide layers. The etch stop layer 208 is deposited onto the first substrate 318A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 320 can then be selectively etched, stopping at a predetermined depth, while protecting the underlying layers. After the etching process, the remaining photoresist can be removed through stripping techniques. While in some embodiments, SiGe is used to form the etch stop layer 320, in some embodiments, silicon nitride (SiN), silicon oxide (SiO2), or silicon oxynitride (SiON) can be used as the etch stop layer 320.

In some embodiments, the NS 322 can be formed by alternating layers of Si layers and SiGe layers, in which sidewalls of the SiGe layers are indented and covered by the inner spacers. The SiGe layers can subsequently be removed and replaced with gate region materials.

The spacers 334 can be thin insulating layers or materials placed on the sidewalls of the gate regions 312. The spacers 334 can help control the effective channel length of the latch-up prone region 300A. In an embodiment, the spacers 334 can allow for control over the channel's conductive properties, including resistance and carrier mobility, which can contribute to improved performance of the semiconductor device. The spacers 334 can be a low-k material.

In some embodiments, the spacers 334 can act as insulating layers between the gate regions 312 and the set of N-type doped regions 310B and the set of P-type doped regions 310A. That is, the spacers 334 can help prevent current leakage or short circuits between the gate regions 312 and the set of N-type doped regions 310B and the set of P-type doped regions 310A. Such isolation can help maintain the integrity of the passive device's electrical operation and prevent unintended current flow that could negatively impact the performance of the semiconductor device and reliability.

In further embodiments, the spacers 334 can be utilized to modulate the overlapping capacitance between the gate regions 312 and the set of N-type doped regions 310B and the set of P-type doped regions 310A. Overlapping capacitance can affect the passive device's electrical characteristics, such as threshold voltage and switching behavior. Thus, by adjusting the thickness and material properties of the spacers 334 the overlapping capacitance can be optimized, which can allow for better control and modulation of the passive device's behavior. In several embodiments, the spacers 334 can help mitigate the short-channel effects by physically separating the gate regions 312 from the set of N-type doped regions 310B and the set of P-type doped regions 310A. To that end, the spacers 334 can create a barrier that restricts the extension of the electric field into the channel region. This mitigation can improve the device's performance, reduce power consumption, and enhance overall device reliability.

In an embodiment, the spacers 334 can serve as barriers that prevent the lateral diffusion of dopant atoms from the set of N-type doped regions 310B and the set of P-type doped regions 310A, and into the channel region during the doping process. Such diffusion can alter the channel characteristics and compromise the passive device's performance. By confining the dopant diffusion, the spacers 334 can contribute to maintaining the desired device's characteristics and electrical behavior. In some embodiments, the spacers 334 can be formed over the sidewalls of the gate regions 312. The spacers 334 can be formed by deposition techniques. Alternatively, the spacers 334 can be formed by etching or selectively epitaxially growing the spacers 334 over the sidewalls of the gate regions 312. In various embodiments, the spacers 334 can include SiGe. In some embodiments, the STI 216 can be made of SiN, and the ILD 332 can be made of SiO2.

In some embodiments, carrier wafer bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices.

The gate regions 312 can be formed between the set of N-type doped regions 310B and the set of P-type doped regions 310A, and between the S/D 340. A replacement metal gate (RMG) process can be used to fabricate metal gate electrodes. In some embodiments, RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability. In order to fabricate the CA 324 and CA 342, portions of the ILD 332 and 350, the gate regions 312, the STI 316 and STI 358 are removed and filled with a suitable material to form the CA 324 and CA 342.

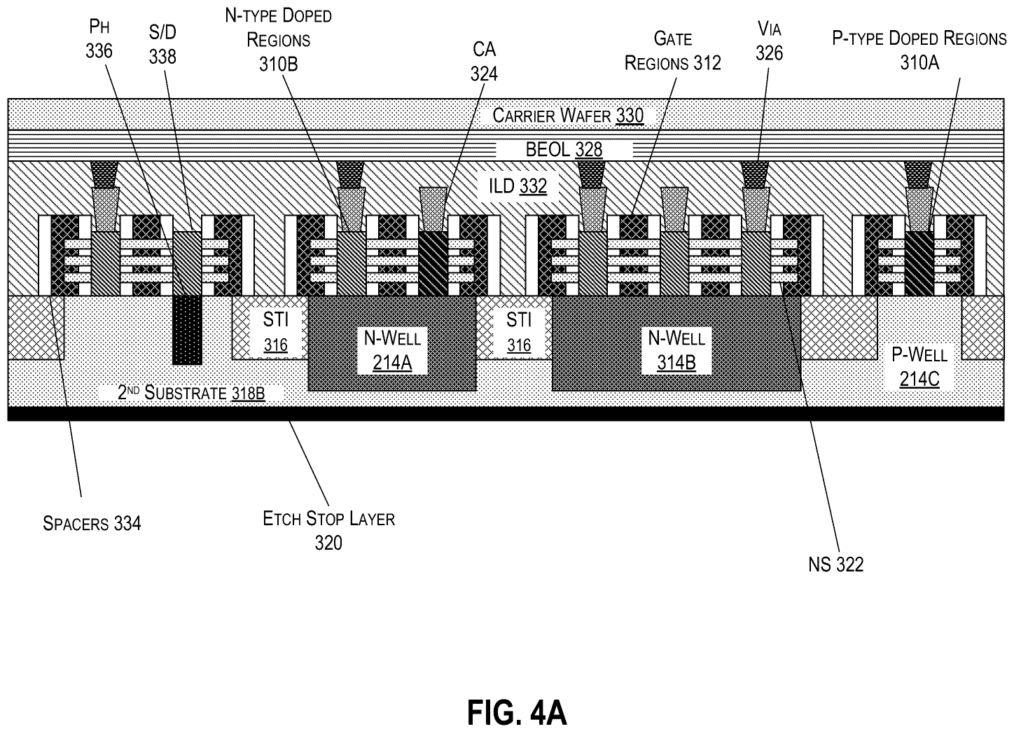

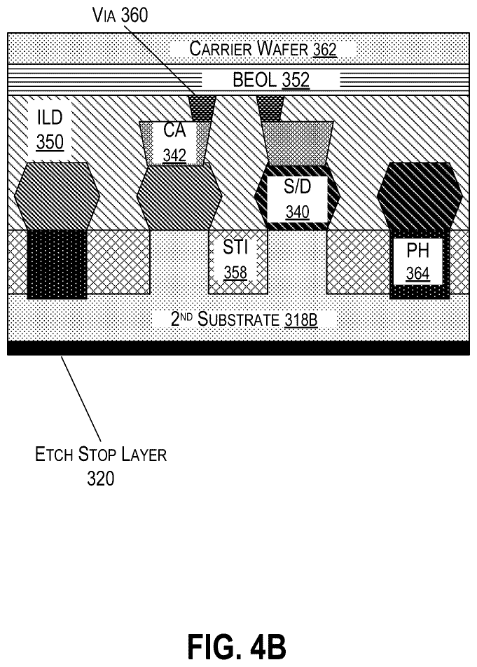

FIGS. 4A-4B illustrate a semiconductor device after the removal of the first substrate, in accordance with some embodiments. In some embodiments, the semiconductor device is flipped and the first substrate is removed. The first substrate removal stops at the etch stop layer 320.

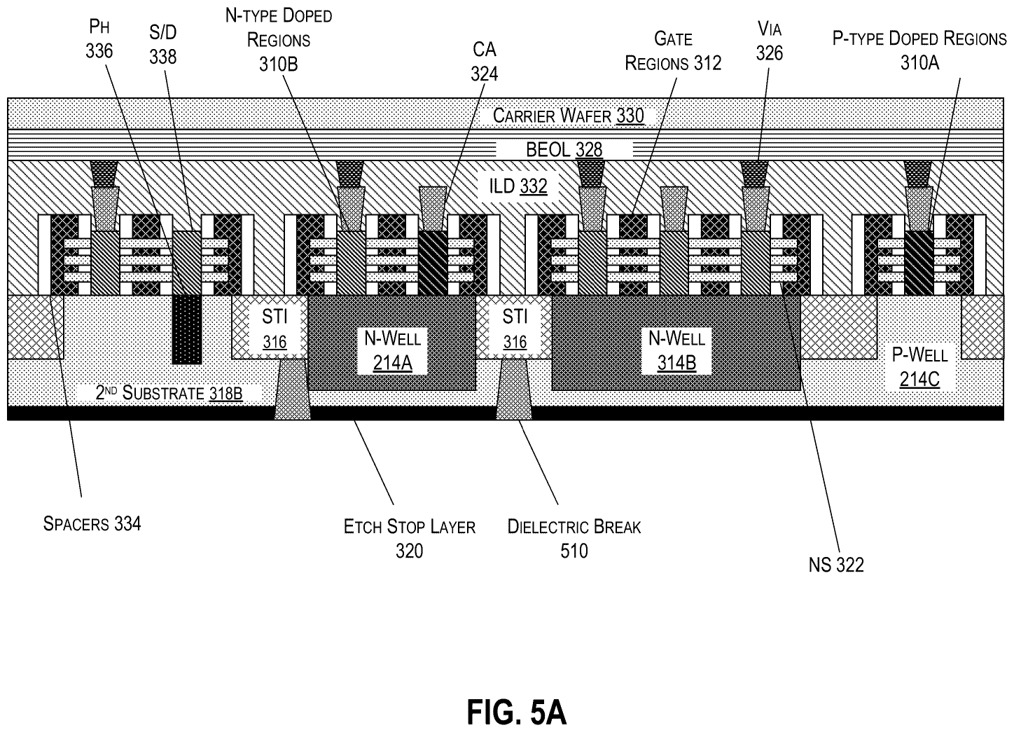

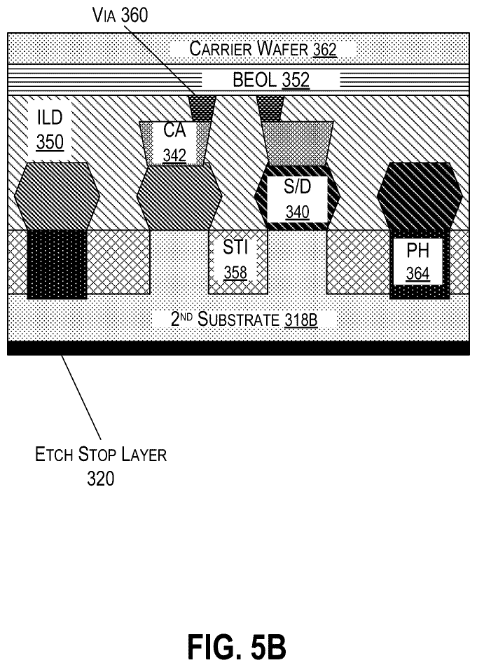

FIGS. 5A-5B illustrate a semiconductor device after the after the formation of the dielectric break, in accordance with some embodiments. In some embodiments, portions of the etch stop layer 320 and the second substrate 318B are removed and filled with silicon to form the dielectric break 510.

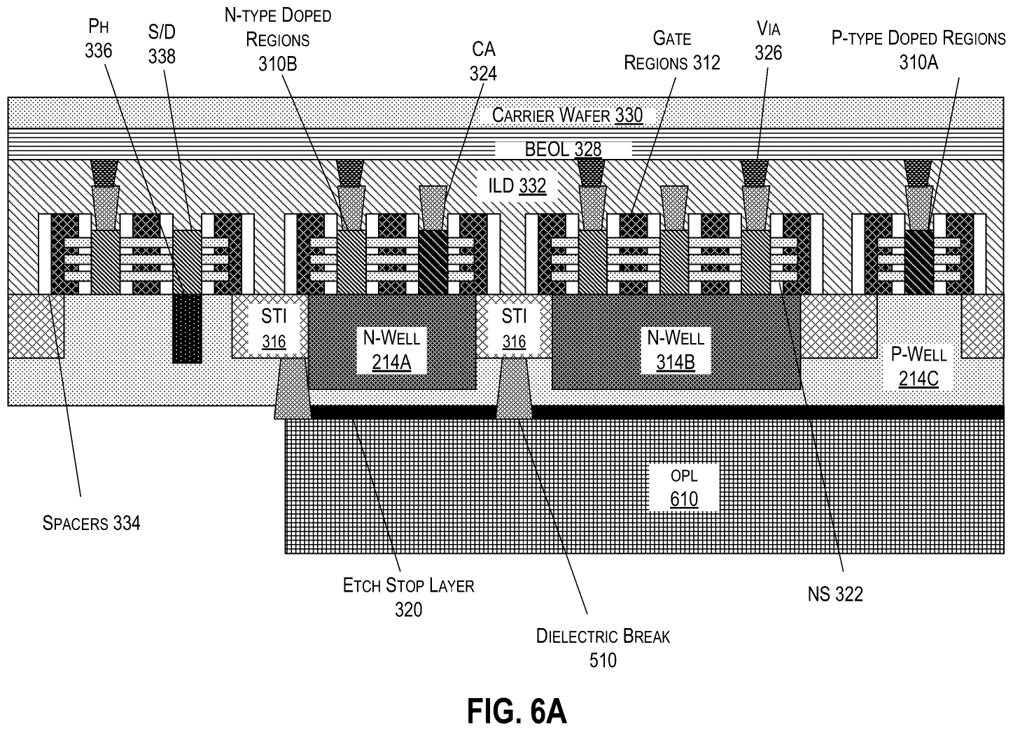

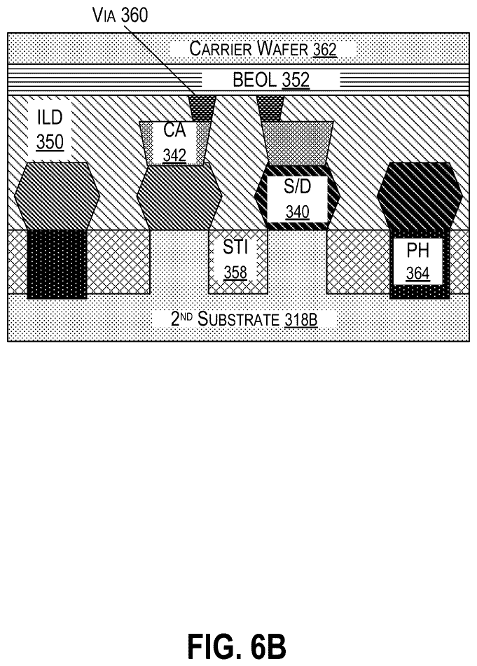

FIGS. 6A-6B illustrate a semiconductor device after the after the removal of the etch stop layer, in accordance with some embodiments. In some embodiments, an organic planarization layer, OPL 610, is formed over passive device 620. The OPL 610 can include a photo-sensitive organic polymer having a light-sensitive material that, when exposed to electromagnetic radiation, is chemically altered and thus configured to be removed using a developing solvent. For example, in some embodiments, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene. In some embodiments, the OPL 610 can include any organic polymer and a photoactive compound having a molecular structure that can attach to the molecular structure of the organic polymer. In some embodiments, the OPL 610 material is selected to be compatible with an overlying antireflective coating and/or an overlying photoresist. In some embodiments, the OPL 610 can be applied using spin coating technology, although other techniques are within the contemplated scope of the present disclosure. Subsequently, the exposed portions of the etch stop layer are removed.

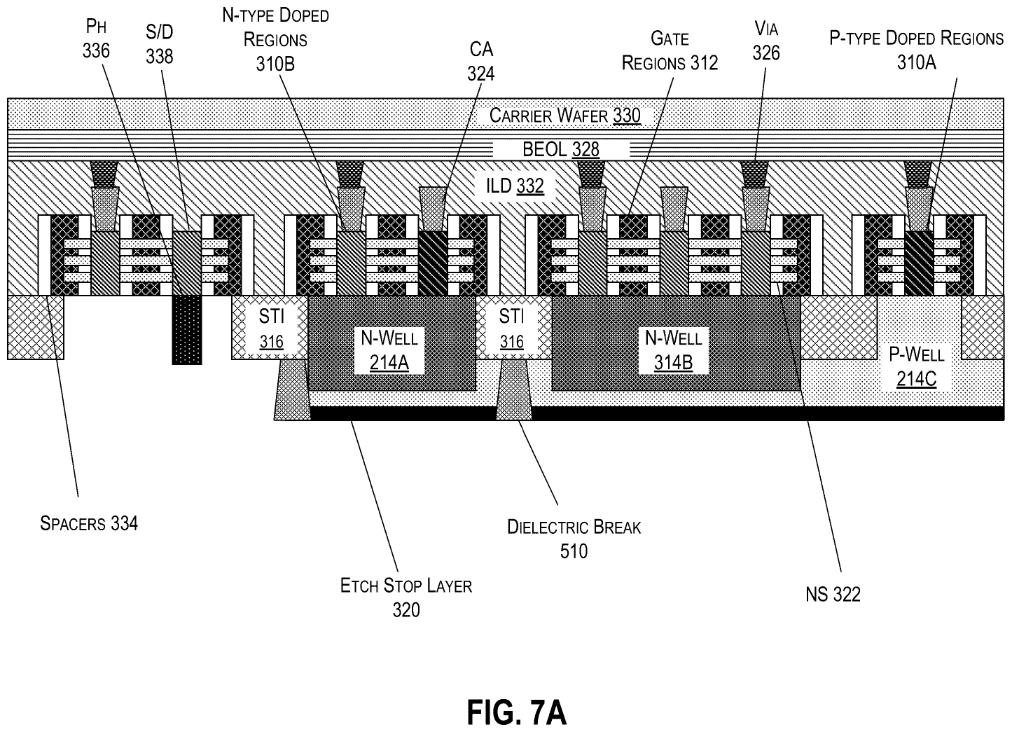

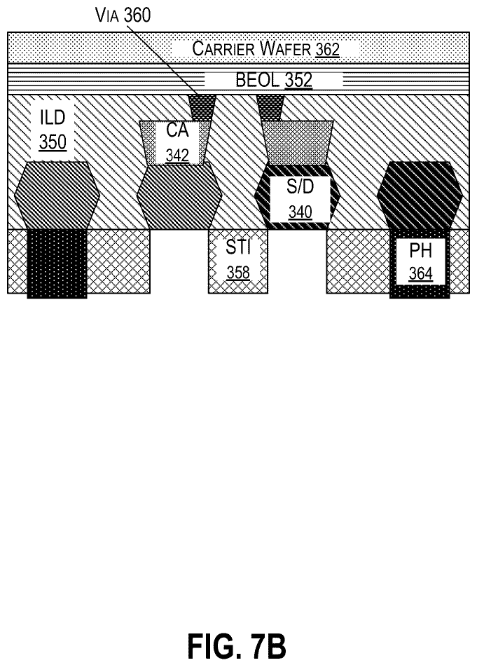

FIGS. 7A-7B illustrate a semiconductor device after the removal of the organic planarization layer, in accordance with some embodiments. In some embodiments, the OPL covering the passive device, and the second substrate are removed.

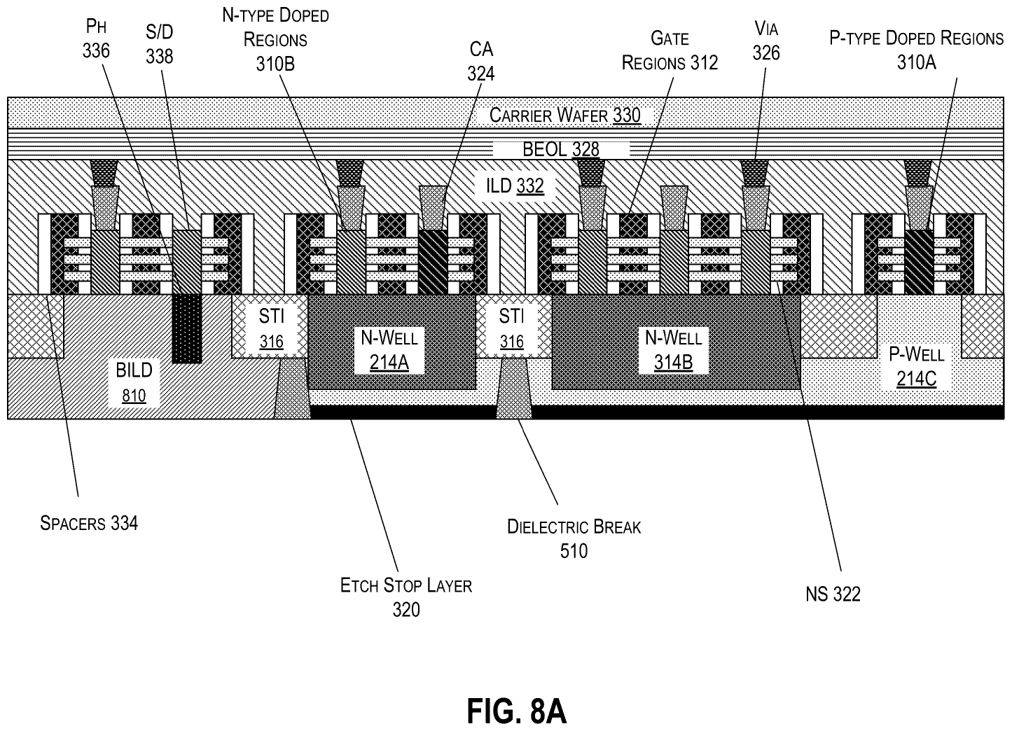

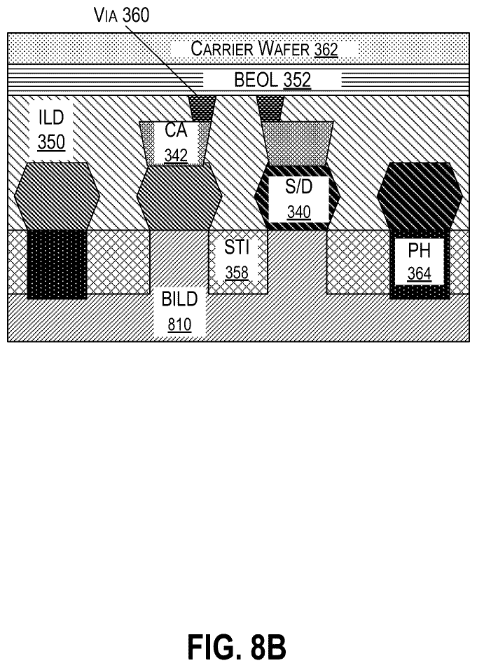

FIGS. 8A-8B illustrate a semiconductor device after the formation of the bottom dielectric layer, in accordance with some embodiments. In some embodiments, the backside dielectric, BILD 810, is formed over the semiconductor device. In various embodiments, the BILD 810 can function as a protective layer, shielding the active regions of the semiconductor device from external contaminants, moisture, and mechanical stress. The BILD 810 can further help prevent physical damage, such as scratches or particle contamination, which could adversely affect semiconductor device performance. Additionally, the BILD 810 can function as a barrier against moisture ingress, which can cause corrosion and degradation of the semiconductor device's components. The BILD 810 can be made of SiO2. In an embodiment, a chemical-mechanical polishing (CMP) process is further processed after the formation of the BILD 810.

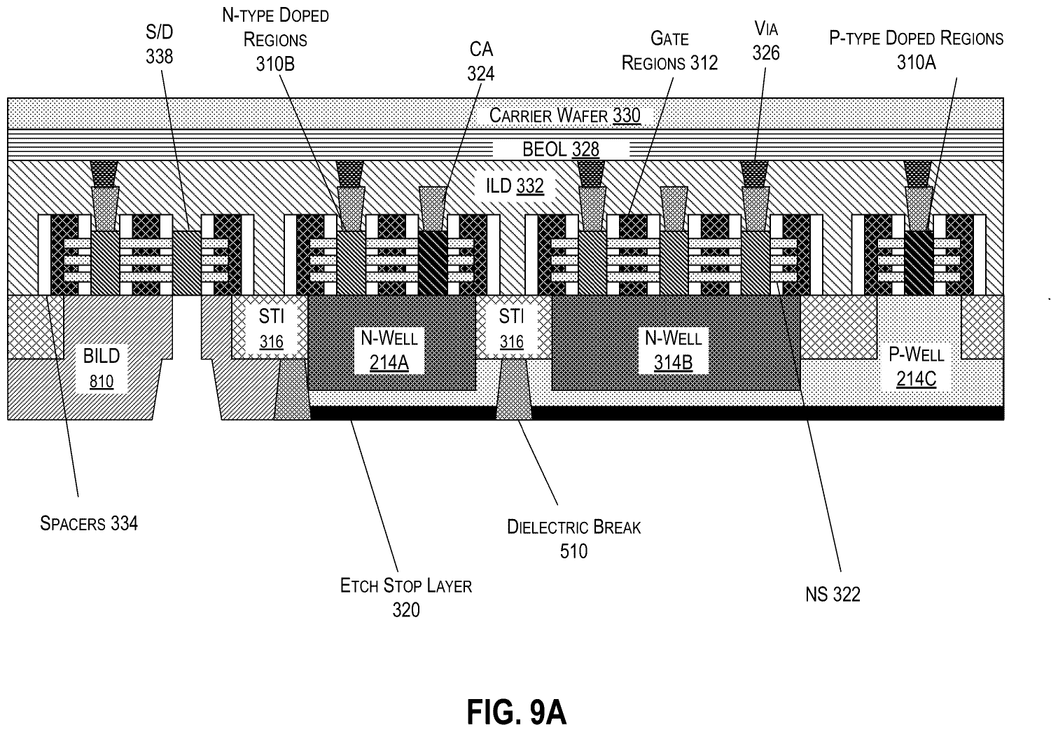

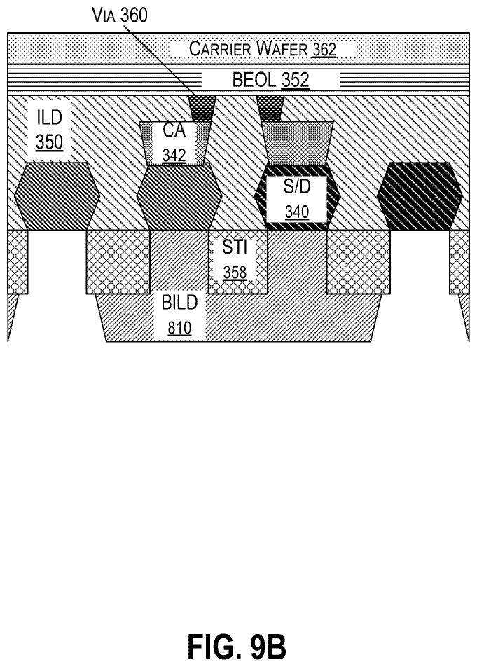

FIGS. 9A-9B illustrate a semiconductor device after the removal of the placeholders, in accordance with some embodiments. In some embodiments, portions of the BILD 810 from the active device are removed. Then, the backside contacts are patterned by removing the PH 336 and PH 364 and exposing the bottom of the set of N-type doped regions 310B and the set of P-type doped regions 310A in the passive device and the S/D 340 in the active device.

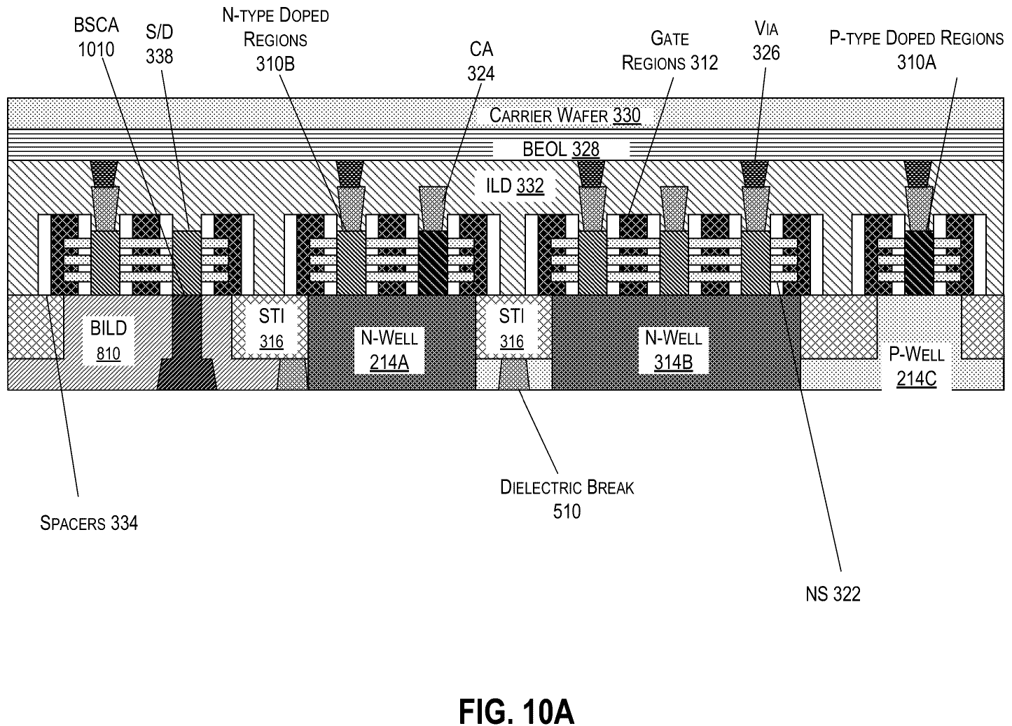

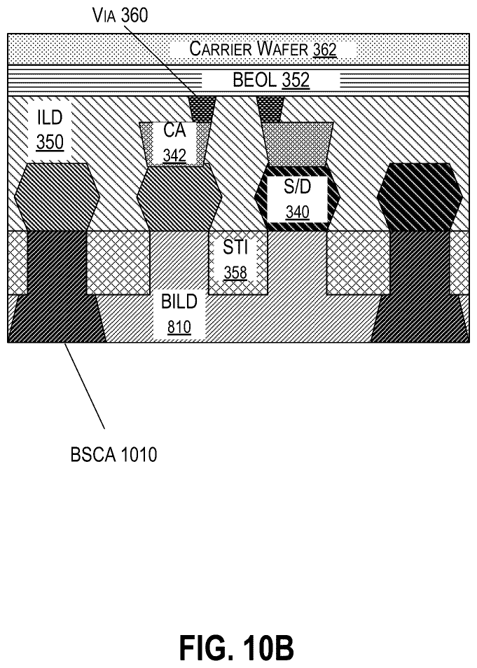

FIGS. 10A-10B illustrate a semiconductor device after the backside contact metallization, in accordance with some embodiments. In some embodiments, the remaining etch stop layer is removed and the backside contacts, BSCA 1010, are formed by filling the recessed areas with a suitable metal. The BSCA 1010 is surrounded in by the BILD 810. Portions of the second substrate are further removed from the passive device to expose the first N-well region 314A, the second N-well region 314B, and the P-well region 314C.

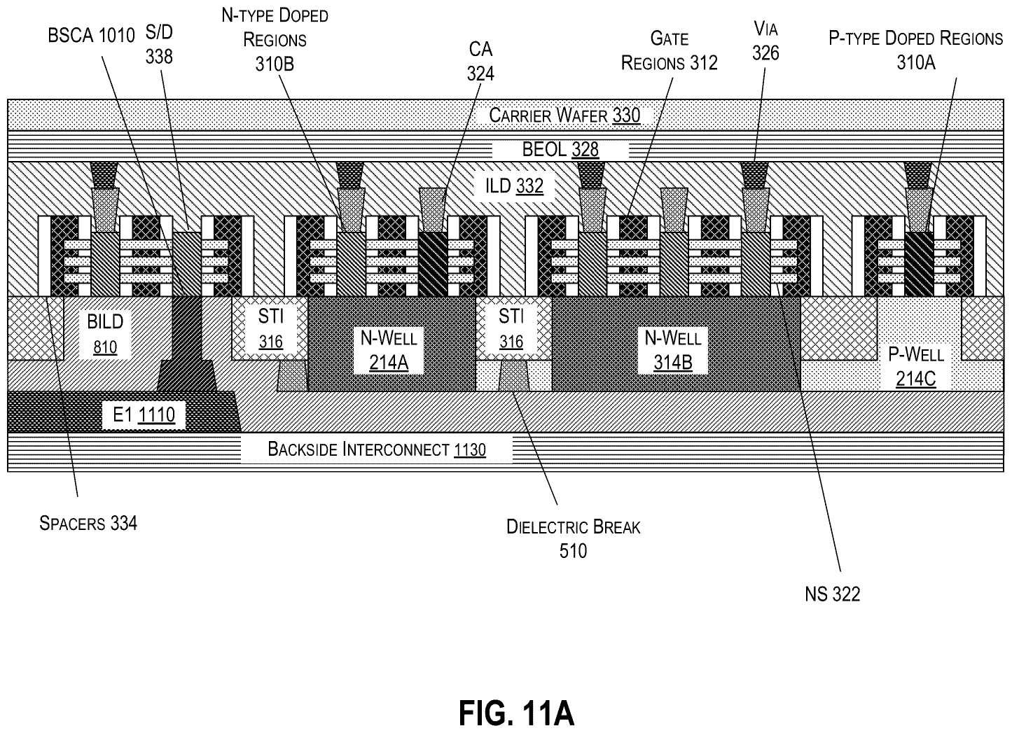

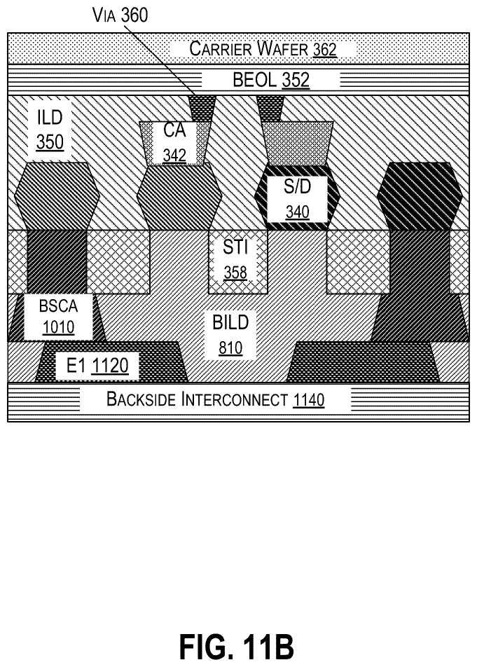

FIGS. 11A-11B illustrate a semiconductor device after the formation of the backside metal lines and backside interconnects, in accordance with some embodiments. In some embodiments, a backside metal line, E1 1110 and E1 1120 are formed over the BILD 810 in the active device. A backside interconnect 1130 and backside interconnect 1140 are formed over the backside of the semiconductor device. As a result, the set of N-type doped regions 310B in the active region of the latch-up prone region 1100A and the S/D 340 in the active device 1100B can be connected to the backside interconnect 1130 and backside interconnect 1140 via the E1 1110 and E1 1120, respectively.

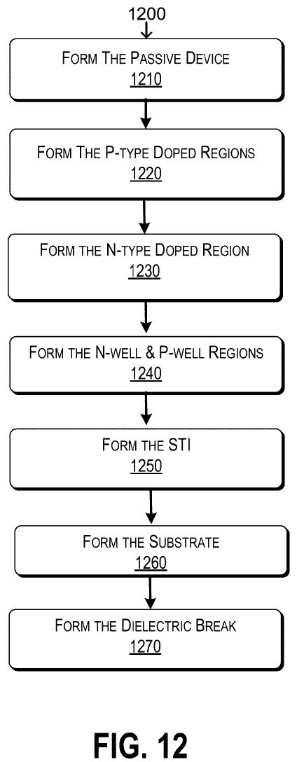

FIG. 12 illustrate a block diagram of a method 1200 for forming the semiconductor device, in accordance with some embodiments. As shown by block 1210, the passive device is formed.

As shown by block 1220, the set of P-type doped regions are formed.

As shown by block 1230, the set of N-type doped regions are formed.

As shown by block 1240, the N-well regions and P-well regions are formed below the set of N-type doped regions and the set of P-type doped regions.

As shown by block 1250, an STI is formed.

As shown by block 1260, a substrate is formed below the STI.

As shown by block 1270, a dielectric break is formed within the substrate. The dielectric break is vertically extended form the STI to a BILD below the substrate.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a passive device comprising:
a set of P-type doped regions;
a set of N-type doped regions;
a first N-well region and a second N-well region below the set of P-type doped regions and the set of N-type doped regions;
a first shallow trench isolation (STI) between the first N-well region and the second N-well region;
a substrate below the first STI; and
a dielectric break within the substrate, wherein the dielectric break is vertically extended from the first STI to a bottom interlayer dielectric (BILD) below the substrate.

2. The semiconductor device of claim 1, wherein the dielectric break and the first STI isolate the first N-well region and the second N-well region.

3. The semiconductor device of claim 1, wherein the dielectric break is made of silicon.

4. The semiconductor device of claim 1, wherein the passive device is electrically connected to a back end of line (BEOL) through a first via.

5. The semiconductor device of claim 1, further comprising:
an active device, comprising:
source/drain regions;
gate regions; and
a backside contact.

6. The semiconductor device of claim 5, wherein the active device is a field-effect transistor (FET).

7. The semiconductor device of claim 5, wherein the active device further comprises alternative layers extended horizontally between two adjacent source/drain regions.

8. The semiconductor device of claim 5, wherein the active device is electrically connected to a back end of line (BEOL) through a second via.

9. The semiconductor device of claim 7, wherein the alternative layers include silicon.

10. A method for fabrication of a semiconductor device, the method comprising:
forming a passive device comprising:
forming a set of P-type doped regions;
forming a set of N-type doped regions;
forming a first N-well region and a second N-well region below the set of P-type doped regions and the set of N-type doped regions;
forming a first shallow trench isolation (STI) between the first N-well region and the second N-well region;
forming a substrate below the first STI; and
forming a dielectric break within the substrate, wherein the dielectric break is vertically extended form the first STI to a bottom interlayer dielectric (BILD) below the substrate.

11. The method of claim 10, further comprising isolating the first N-well region and the second N-well region by the dielectric break and the first STI.

12. The method of claim 10, wherein the dielectric break is made of silicon.

13. The method of claim 10, further comprising establishing an electrical connection between the passive device and a back end of line (BEOL) through a first via.

14. The method of claim 10, further comprising:
forming an active device, comprising:
forming source/drain regions;
forming gate regions between the source/drain regions; and
forming a backside contact below one of the source/drain regions.

15. The method of claim 14, wherein the active device is a field-effect transistor (FET).

16. The method of claim 14, further comprising forming alternative layers extended horizontally between two adjacent source/drain regions.

17. The method of claim 16, further comprising establishing an electrical connection between the active device and a back end of line (BEOL) through a second via.

18. The method of claim 17, wherein the alternative layers include silicon.

19. A semiconductor device, comprising:
a passive device comprising:
a shallow trench isolation (STI);
a substrate below the STI; and
a dielectric break within the substrate, wherein the dielectric break and the STI isolate a first N-well region and a second N-well region in the passive device; and
an active device.

20. The semiconductor device of claim 19, wherein the passive device further comprises:
a set of P-type doped regions; and
a set of N-type doped regions, wherein:
the first N-well region and the second N-well region are located below the set of P-type doped regions and the set of N-type doped regions.
